(19) United States
(12) Patent Application Publication
(10) Pub. No.: US 2015/0280175 A1
(43) Pub. Date: Oct. 1, 2015

(54) METHOD FOR MANUFACTURING ORGANIC LIGHT EMITTING ELEMENT

(71) Applicant: CANON KABUSHIKI KAISHA, Tokyo (JP)

(72) Inventors: Takayuki Ito, Kawasaki-shi (JP); Itaru Takaya, Tokyo (JP); Seiji Mashimo, Yokohama-shi (JP); Koji Ishizuya, Kawasaki-shi (JP); Jun Kamatani, Tokyo (JP); Naoki Yamada, Inagi-shi (JP); Tetsuya Kosuge, Yokohama-shi (JP); Hirokazu Miyashita, Tokyo (JP)

(21) Appl. No.: 14/668,660

(22) Filed: Mar. 25, 2015

(30) Foreign Application Priority Data
Mar. 27, 2014 (JP) 2014-067098
Sep. 10, 2014 (JP) 2014-184400
Sep. 10, 2014 (JP) 2014-184401
Jan. 23, 2015 (JP) 2015-011628

(51) Int. Cl. H01L 51/56; H01L 51/52; H01L 51/00

(52) U.S. Cl. CPC H01L 51/56; H01L 51/008; H01L 51/5253; H01L 51/5012

(57) ABSTRACT

This invention provides a method for manufacturing an organic light emitting element in which damages to members constituting the organic light emitting element are suppressed and a protective layer with few defects is formed by performing cleaning with liquid containing water. The manufacturing method according to this invention is a method for manufacturing an organic light emitting element including a process of preparing a lower electrode, a process of forming an organic compound layer on the lower electrode, a process of forming an upper electrode on the organic compound layer; and a process of forming a first protective layer on the upper electrode,
in which the method includes, after the process of forming the organic compound layer, a process of cleaning at least one of the organic compound layer, the upper electrode, and the first protective layer with liquid containing water.

### BACKGROUND OF THE INVENTION

1. Field of the Invention

The present invention relates to a method for manufacturing an organic light emitting element.

2. Description of the Related Art

An organic light emitting element is an element having an anode, a cathode, and an organic compound layer disposed therebetween. The organic light emitting element emits light when holes injected from the anode and electrons injected from the cathode are recombined in a light emitting layer, so that excitons are generated, and then the excitons return to the fundamental state.

The organic light emitting element has been expected to reduce the thickness and the weight. Therefore, as a method for sealing the organic light emitting element, not former cap sealing employing metal and glass but a sealing method for forming a protective film (passivation film) on the element is known. As the sealing method employing a protective film, a technique of covering the organic light emitting element with a silicon nitride (SiN) film by a CVD method is known, for example. From the viewpoint of blocking moisture and oxygen to protect the organic light emitting element, the protective film has been demanded to have high density and high coverage.

It is known that when moisture and oxygen enter the inside of the organic light emitting element, the organic light emitting element is degraded. For example, when an electron injection layer and a cathode constituting the organic light emitting element react with moisture, the electron injection properties of the reacted region decrease in some cases. The region where the electron injection properties are degraded as described above causes a defect of non-light emission which is referred to as a dark spot.

In processes of fabricating the organic light emitting element, for example, in a process of transporting a substrate, a process of forming an organic layer, and the like, foreign matter sometimes adheres to the substrate or the organic light emitting element. When foreign matter has adhered to the organic light emitting element before forming a protective film, an entry path of moisture and oxygen is formed in the formed protective film. The protective film in such a state allows the entry of moisture and oxygen with time, so that the non-light emission region extends, which results in the generation of the dark spot in the organic light emitting element.

On the other hand, even when foreign matter adheres, in the case where the protective film is thickly formed so that the entry path of moisture and oxygen is not formed, protection performance from moisture and oxygen is obtained. However, when the protective film is thickly formed, the film formation time is sharply prolonged, which results in an increase in manufacturing cost.

Therefore, in order to form a protective film having high protection performance without prolonging the film formation time of the protective film, it is suitable to remove foreign matter present on the substrate or the organic light emitting element before forming the protective film.

U.S. Patent Application Publication No. 2011/0079815 discloses a technique of cleaning with carbon dioxide particles as a method for removing foreign matter. The removal of foreign matter with carbon dioxide particles does not use moisture. Therefore, the foreign matter can be removed without causing degradation in an organic compound layer due to a reaction with moisture.

The method for removing foreign matter of U.S. Patent Application Publication No. 2011/0079815 has a problem of causing physical damages in the organic compound layer in collision of the carbon dioxide particles. Moreover, also when a foreign matter removing target is an upper electrode, physical damages are similarly caused.

### SUMMARY OF THE INVENTION

The present invention provides a method for manufacturing an organic light emitting element in which an entry path of moisture and oxygen is difficult to be formed in a protective layer by removing foreign matter while suppressing physical damages in an organic compound layer and an upper electrode.

Then, the present invention provides a method for manufacturing an organic light emitting element including a process of forming a lower electrode, a process of forming an organic compound layer having a light emitting layer on the lower electrode, a process of forming an upper electrode on the organic compound layer, a process of forming a first protective layer on the upper electrode and a process of forming a second protective layer on the first protective layer, in which the method includes a process of cleaning at least one of the organic compound layer, the upper electrode, or the first protective layer with liquid containing water.

Further features of the present invention will become apparent from the following description of exemplary embodiments with reference to the attached drawings.

### BRIEF DESCRIPTION OF THE DRAWINGS

FIG. 1 is a schematic view illustrating an example of a process of performing cleaning with liquid containing water in a method for manufacturing an organic light emitting element of the present invention.

FIG. 2 is a flow chart showing an example of the method for manufacturing an organic light emitting element of the present invention.

FIG. 3 is a schematic view illustrating an example of an image formation apparatus according to the present invention.

### DESCRIPTION OF THE EMBODIMENTS

The present invention is a method for manufacturing an organic light emitting element including a process of forming a lower electrode, a process of forming an organic compound layer having a light emitting layer on the lower electrode, a process of forming an upper electrode on the organic compound layer, a process of forming a first protective layer on the upper electrode, a process of forming a second protective layer on the first protective layer, in which the method includes a process of cleaning at least one of the organic compound layer, the upper electrode, or the first protective layer with liquid containing water.

The process of performing cleaning with liquid containing water in this embodiment is a process of removing foreign matter on or inside the formed layers.

In this embodiment, the liquid containing water is liquid containing water as the main component and refers to one in which the weight ratio of water is 50% by weight or more when the weight of the entire liquid is 100% by weight. When the weight of the entire liquid is 100%, the weight ratio of water is suitably 80% or more and more suitably 90% or more. The cleaning using the liquid containing water is suitable because the influence on the organic compound is smaller than that of cleaning using an organic solvent.

The liquid containing water may contain an additive. Specifically, the additive is at least one kind of a surfactant, carbon dioxide, an antistatic agent, and a lubricant. When carbon dioxide is contained, re-adhesion of foreign matter due to electrostatic force can be suppressed, and thus the use thereof is suitable.

It is suitable for the liquid containing water to have a boiling point of 100° C. or higher and 200° C. or less. This is because when removing the liquid from the organic light emitting element after cleaning, the liquid is easily evaporated.

The process of performing cleaning with liquid containing water according to the present invention may include cleaning any one or each of the organic compound layer, the upper electrode, and the protective layer.

The cleaning of each layer may be performed in such a manner that the organic compound layer is cleaned, the upper electrode is formed, the upper electrode is cleaned, and then the protective layer is cleaned.

### First Embodiment

This embodiment describes a process of cleaning the upper electrode in the organic light emitting element with liquid containing water.

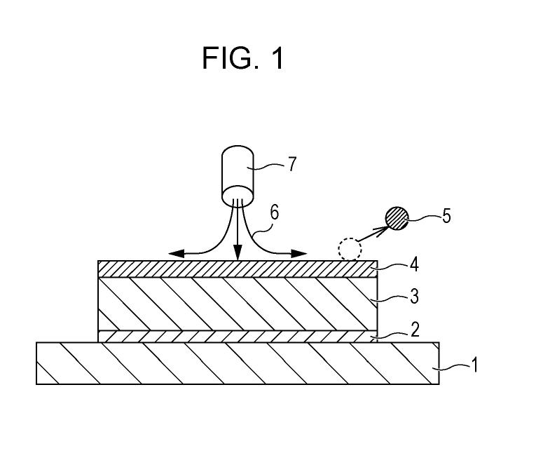

FIG. 1 is a schematic view illustrating a process of cleaning the upper electrode with liquid containing water after forming the upper electrode. On a substrate 1, a lower electrode 2, an organic compound layer 3, and an upper electrode 4 are formed. Foreign matter 5 on the upper electrode 4 is removed by liquid containing water 6 supplied from a nozzle 7.

When performing the process of performing cleaning with liquid containing water, the cleaning may be performed while a cleaning target, i.e., the upper electrode 4, and the nozzle 7 may relatively move.

The cleaning process with liquid containing water includes methods, such as two fluid cleaning, ultrasonic cleaning, microbubble cleaning, and high-pressure spray cleaning and is not limited thereto insofar as cleaning is performed with liquid containing water.

It is suitable for the cleaning process with liquid containing water to use the two fluid cleaning having a high foreign matter removal ratio. The two fluid cleaning includes mixing liquid serving as two fluid with gas to form water particles having a fine particle diameter, and then spraying the water particles to a substrate by a nozzle to thereby remove foreign matter and wastes on the substrate. As the gas to be used, inactive gas, such as nitrogen and argon, can be used.

The parameters which determine the cleaning effect of the two fluid cleaning include the gas flow rate, the liquid flow rate, the cleaning time, and the like. The removal ratio of foreign matter varies depending on the parameters. It is suitable that nitrogen gas is used as the gas and pure water is used as the liquid.

When the two fluid cleaning is performed, it is desirable to perform the cleaning under the conditions of a nitrogen flow rate of 10 L/min or more and 180 L/min or less and the pure water flow rate of 0.05 L/min or more and 2.0 L/min or less.

For the two fluid cleaning, a method for swinging a two fluid nozzle on the substrate while rotating the substrate at a certain speed for cleaning is suitably used. The substrate rotation speed in cleaning is suitably 100 rpm or more and 2000 rpm or less.

Instead of performing cleaning while rotating the substrate, a method including performing cleaning while transporting the substrate under a nozzle array in which two fluid nozzles are disposed side by side at a certain interval may be acceptable.

By cleaning the substrate under the conditions described above, foreign matter, wastes, and the like present inside or on the film can be removed while suppressing damages to members constituting the organic light emitting element and film separation. When the cleaning process is not performed, foreign matter is present on the substrate and the organic light emitting element, an entry path of moisture and oxygen may be formed in the protective layer.

In removal traces formed after the foreign matter removal by the cleaning process, a non-light emission region of sub μm to several tens μm arises from the boundary portion of the removal traces depending on the degree of the water resistance of members constituting the organic light emitting element. However, the non-light emission region does not extend with time due to storage or drive of the organic light emitting element after manufacturing the organic light emitting element, and therefore the reliability of products is not affected. Therefore, when the non-light emission region has a size which does not pose problems in terms of functions, the organic light emitting element can be applied to products.

Although the process of performing cleaning with liquid containing water according to the present invention is suitably performed under an inactive gas atmosphere, such as nitrogen and argon, the process can be performed in the air. However, when the organic compound layer is irradiated with environment light including ultraviolet light to visible light in a state where the organic compound layer is exposed to the air, the organic compound of the organic compound layer causes a chemical reaction with oxygen and moisture in the air to cause degradation in the organic compound layer in some cases. When the organic compound layer is degraded, an increase in voltage and a reduction in luminous efficiency and durability properties of the organic light emitting element are caused in some cases. Therefore, when performing the process in the air environment, it is suitable to reduce the energy of the spectral end on the short wavelength side of the environment light to be lower than at least the excited singlet state of the organic compound contained in the light emitting layer in the organic compound layer in order to prevent the degradation of the organic compound. Specifically, the degradation of the organic compound can be suppressed by changing the environment light to yellow fluorescent light or red light for use in manufacturing of a semiconductor. The degradation of the organic compound can also be suppressed by blocking light in such a manner that the organic compound layer is not irradiated with light.

After the cleaning, a process of drying the liquid containing water may be provided. For example, it is suitable to set the number of rotations of the substrate to 500 rpm or more and 4000 rpm or less after the two fluid cleaning, and then perform spin drying. The drying is performed under the conditions where the drying time is 30 seconds or more and 3 minutes or less and water droplets do not remain on the substrate.

Furthermore, the method for manufacturing an organic light emitting element of the present invention may further have a process of performing heating under reduced pressure after the cleaning. By heating, the liquid containing water for use in the cleaning can be efficiently removed from the organic light emitting element.

The heating temperature is suitably 50° C. or higher and more suitably 115° C. or higher. The heating temperature is more suitably in the range of temperatures equal to or less than the glass transition temperature of the organic compound of the organic light emitting element. More specifically, the heating temperature is suitably 115° C. or higher and equal to or less than the glass transition temperature of the organic compound of the organic light emitting element.

### Second Embodiment

This embodiment describes a process of cleaning the organic compound layer in the organic light emitting element with liquid containing water. The cleaning method is the same as that of the first embodiment.

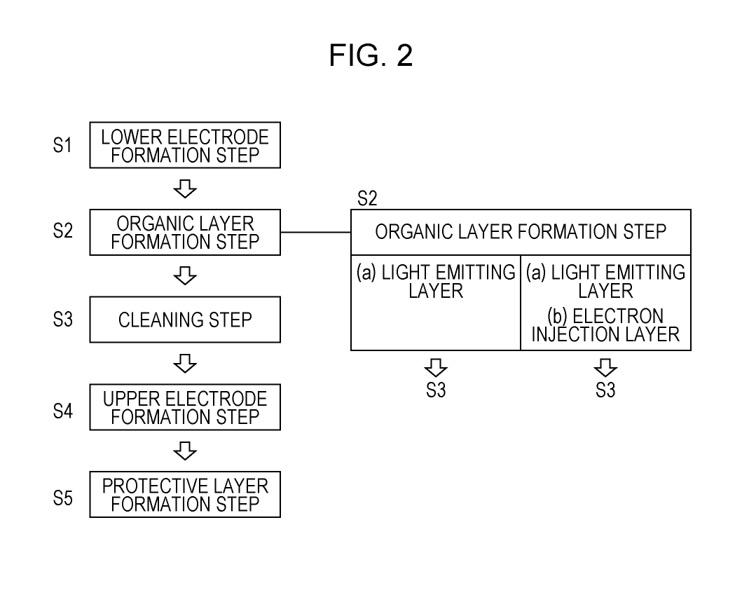

FIG. 2 is a flow chart showing a method for manufacturing an organic light emitting element according to this embodiment. The method for manufacturing an organic light emitting element according to this embodiment has processes S1 to S5 in order. S1 is a process of forming a lower electrode on a substrate, S2 is a process of providing at least one organic compound layer, S3 is a process of cleaning the organic compound layer with liquid containing water, S4 is a process of forming an upper electrode, and S5 is a process of forming a protective layer.

S2 may have an aspect of forming at least a light emitting layer, and then proceeding to S3 (S2(a)) or may have an aspect of forming at least a light emitting layer and an electron injection layer, and then proceeding to S3 (S2(b)).

In the case of S2(a), S3 includes cleaning the light emitting layer. In the case of S2(b), S3 includes cleaning the electron injection layer.

S3 is a process of directly cleaning the organic compound layer with liquid containing water. The cleaning process may be performed after completing the formation of the organic compound layer or in the middle of the process of forming the organic compound layer. The cleaning process in the middle of the process of forming the organic compound layer refers to a process of forming the organic compound layer again after the cleaning process.

After S3 in this embodiment, a process of drying the liquid containing water may be provided. The drying method is the same as that of the first embodiment.

Moreover, a process of performing heating under reduced pressure may be provided similarly as in the first embodiment.

### Third Embodiment

This embodiment describes a process of cleaning the first protective layer in the organic light emitting element with liquid containing water.

The first protective layer to be cleaned in this embodiment is the protective layer formed on the upper electrode. The cleaning method is the same as that of the first embodiment.

After cleaning the first protective layer, a second protective layer can also be formed. When the second protective layer is formed, the second protective layer is a dense layer which is difficult to form an entry path of moisture and oxygen. This is because foreign matter on or inside the first protective layer is removed.

After the process of cleaning the first protective layer in this embodiment, a process of drying the liquid containing water may be provided. The drying method is the same as that of the first embodiment.

Moreover, a process of performing heating under reduced pressure may be provided similarly as in the first embodiment.

The method for manufacturing an organic light emitting element according to the present invention may have the following processes:

(A) a process of forming a lower electrode,
(B) a process of forming an organic compound layer on the lower electrode,
(C) a process of cleaning the organic compound layer with liquid containing water,
(D) a process of forming an upper electrode on the organic compound layer,
(E) a process of cleaning the upper electrode with liquid containing water,
(F) a process of forming a first protective layer contacting the upper electrode,
(G) a process of cleaning the first protective layer with liquid containing water, and
(H) a process of forming a second protective layer on the first protective layer.

The processes (C), (E), and (G) are the cleaning processes described in the first to third embodiments. The present invention may have at least one of the processes. It is a matter of course that all the processes of C, E, and G may be included.

Hereinafter, processes other than the cleaning process in the method for manufacturing an organic light emitting element according to the present invention are described.

### (A) Process of Forming Lower Electrode

A lower electrode is formed on a substrate. A substrate on which a lower electrode is formed beforehand may be prepared. The substrate is formed with materials capable of supporting an organic compound layer and an electrode, and glass, plastic, silicon, and the like are suitable. On the substrate, a switching device, such as TFT, may be formed.

The lower electrode may contain any material insofar as the material is a conductive material. Particularly in the case where light is extracted from the substrate side (bottom emission), the lower electrode is suitably formed with transparent conductive oxides typified by ITO and the like, semi-light-transmissive metals or semi-light-transmissive alloys, semi-light-transmissive metal nanowire, and conductive polymers, such as PEDOT-PSS, from the viewpoint of light transmission properties.

In the case where light is extracted from the side opposite to the substrate (top emission), the lower electrode is suitably a reflective electrode formed with metals or alloys thereof, so that the light emitted from the light emitting layer is reflected to increase the luminous efficiency. Specifically, materials, such as Al, Ag, Pt, Au, Cu, Pd, Ni, and Mo, are suitable. The reflective electrode may be a laminate in which a metal layer and a transparent conductive oxide, such as ITO, are laminated.

The lower electrode can be formed by known methods, such as a vacuum evaporation method and a sputtering method.

The lower electrode can be formed at a predetermined position by patterning. Known methods can be used as a method for patterning the lower electrode. On an edge portion of the lower electrode, an insulating film may be formed.

After the pattern formation of the lower electrode, it is suitable to perform a process of removing foreign matter on the lower electrode and a process of modifying the surface of the lower electrode. For example, argon plasma treatment, oxygen plasma treatment, UV irradiation treatment, heat treatment, and the like are mentioned. It is suitable to perform the treatment above to regulate the charge injection properties of the lower electrode and also remove contamination and the like on the lower electrode.

### (B) Process of Forming Organic Compound Layer on Lower Electrode

Next, an organic compound layer is formed on the lower electrode. As methods for forming the organic compound layer, known techniques, such as a vacuum deposition method, an ink-jet method, a spin coating method, and a nozzle coating method, can be used. The organic compound layer may be a laminate of a plurality of layers. The details of the organic compound layer are described later.

### (D) Process of Forming Upper Electrode on Organic Compound Layer

Next, an upper electrode is formed on the organic compound layer. For the formation of the upper electrode, known film formation techniques can be used. In particular, a resistance heating vapor deposition method, an induction heating vapor deposition method, an EB (electron beam) vapor deposition method, a sputtering method, and the like in a vacuum are suitable.

The upper electrode is suitably formed in such a manner that the organic compound layer is not exposed to the surface. Due to the fact that the organic compound layer is not exposed to the surface, when the upper electrode is cleaned using liquid containing water, the generation frequency of separation of the organic compound layer can be reduced. Moreover, due to the fact that the organic compound layer is not exposed to the surface, the cleaning conditions can be strengthened, and therefore foreign matter can be more effectively removed.

The upper electrode may be a conductive material. In the case of bottom emission, the upper electrode is suitably a reflective electrode formed with metals or alloys thereof with high reflectivity, so that light emitted from the light emitting layer is reflected to increase the luminous efficiency. Specifically, materials, such as Al, Ag, Pt, Au, Cu, Pd, Ni, Mo, and Mg, are suitable and Al is particularly suitable.

In the case of top emission, semi-light-transmissive metal thin films and transparent conductive oxides typified by ITO and the like can be used. As the semi-light-transmissive metal thin films, the same metals as those of the upper electrode of the bottom emission can be used. A laminate of the semi-light-transmissive metal thin film and the transparent conductive oxide may be acceptable.

### (F) Process of Forming First Protective Layer on Upper Electrode

A first protective layer is a layer provided in order to protect the organic light emitting element from moisture and oxygen which may enter from end portions and an upper portion of a film formation region. In the present invention, the first protective layer is suitably formed in such a manner as to cover the organic compound layer and the upper electrode and is particularly suitably formed on almost the entire region except a region where an external connection terminal is provided.

Constituent materials of the protective layer include silicon nitride, silicon oxide, silicon oxide nitride, and the like. Two or more of the constituent materials may be used to form a laminate. As methods for forming the protective layer, a sputtering method and a CVD method can be used.

An example in the case of forming the first protective layer by a VHF plasma CVD method is described. First, a high-frequency electrode of a deposited film formation apparatus and an earth electrode facing the same are fixed in such a manner as to contact the back surface of the substrate. Next, the reaction space pressure between the high-frequency electrode and the earth electrode is controlled to 100 Pa under flow of SiH₄ gas, N₂ gas, and H₂ gas. Then, a high frequency power is supplied to the high-frequency electrode, whereby the first protective layer can be deposited and formed on the substrate.

The film thickness of the first protective layer is suitably 20 nm or more and 200 nm or less.

### (H) Process of Forming Second Protective Layer Contacting First Protective Layer

A second protective layer is formed in order to suppress the entry of moisture and oxygen into the organic light emitting element from a portion where foreign substance and the like are removed by the cleaning process, so that the organic layer and the like are exposed and the first protective layer which is thinly formed.

The constituent materials and the formation method of the second protective layer are the same as those of the first protective layer. As the constituent materials of the second protective layer, silicon nitride (SiN), silicon oxide (SiO), silicon oxide nitride (SiON), and the like are used. Two or more of the constituent materials may be used to form a laminate. As methods for forming the second protective layer, a sputtering method and a CVD method can be used.

The film thickness of the second protective layer is determined considering humidity resistance, cost, tact, and the like. The film thickness thereof is desirably about 0.3 to about 2 μm.

When the process of performing the cleaning using liquid containing water is not performed after (F), the processes (F) and (H) can be successively performed. More specifically, when the constituent materials of the first protective layer and the second protective layer are the same, the first protective layer and the second protective layer can also be successively formed by the same formation apparatus. When the constituent materials of the first protective layer and the second protective layer are different, the second protective layer can also be formed under different process conditions after forming the first protective layer or the second protective layer can also be formed using a different formation apparatus.

In the organic light emitting element thus fabricated, foreign matter causing defects in the protective layer is removed by cleaning, and therefore the entry of moisture and oxygen is suppressed by the protective layer, so that the organic light emitting element becomes a stable element which is free from the occurrence of defects over a long period of time.

Organic Light Emitting Element According to this Embodiment

Hereinafter, an example of the function and specific materials of each layer of the organic compound layer of the organic light emitting element in the present invention is described. The element configuration of the organic light emitting element according to the present invention includes multilayer type element configurations in which the following functional layers containing organic compounds shown below are laminated on a substrate. Among the organic compound layers, a layer containing a light emitting material is a light emitting layer.

(1) Anode/Light emitting layer/Cathode
(2) Anode/Hole transport layer/Light emitting layer/Electron injection layer/Cathode
(3) Anode/Hole transport layer/Light emitting layer/Electron transport layer/Electron injection layer/Cathode
(4) Anode/Hole injection layer/Hole transport layer/Light emitting layer/Electron transport layer/Electron injection layer/Cathode
(5) Anode/Hole transport layer/Electron blocking layer/Light emitting layer/Hole blocking layer/Electron transport layer/Electron injection layer/Cathode
(6) Anode/Hole injection layer/Hole transport layer/Electron blocking layer/Light emitting layer/Hole blocking layer/Electron transport layer/Electron injection layer/Cathode

However, these element configuration examples are fundamental element configurations. The configuration of the organic light emitting element containing a compound according to the present invention is not limited thereto insofar as the light emitting layer is included.

The organic light emitting element in the present invention may have a configuration in which the lower electrode functions as an anode and the upper electrode functions as a cathode or a configuration in which the lower electrode functions as a cathode and the upper electrode functions as an anode.

The hole injection layer is a layer which increases the hole injection efficiency from the anode to the hole transport layer and an electron acceptor material capable of extracting electrons from the hole transporting material can be used. For example, transition metal oxides, such as MoO₃, and organic materials, such as a tetracyanoquinodimethane derivative and a hexaazatriphenylene derivative, can be used. Moreover, a mixed film of a hole transporting material having an HOMO of 6 eV or less and the electron acceptor material may be used. The hole transporting material having a HOMO of 6 eV or less includes a triarylamine derivative, a phenylene diamine derivative, a stilbene derivative, a phthalocyanine derivative, a porphyrin derivative, poly(vinyl carbazole), poly(thiophene), and other conductive polymers but is not limited thereto.

The hole transport layer is a layer which increases the hole injection efficiency into the light emitting layer and is selected considering the HOMO of the light emitting layer. The hole transport layer includes a triarylamine derivative, a phenylene diamine derivative, a stilbene derivative, a phthalocyanine derivative, a porphyrin derivative, poly(vinyl carbazole), poly(thiophene), and other conductive polymers and is not limited thereto. The hole transport layer may have a lamination configuration containing a plurality of layers and the electron blocking layer for suppressing leakage of electrons from the light emitting layer can also be inserted between the hole transport layer and the light emitting layer.

The light emitting layer is a layer containing substances having high light emission properties. The substances having high light emission properties may be used singly but it is suitable to dope host materials with a small amount of the substances having high light emission properties. The host materials include a triarylamine derivative, a phenylene derivative, condensed ring aromatic compounds (for example, a naphthalene derivative, a phenanthrene derivative, a fluorene derivative, a chrysene derivative, and the like), organic metal complexes (for example, organic aluminium complexes, such as 8-quinolinolate)aluminum, an organic beryllium complex, an organic iridium complex, an organic platinum complex, and the like), and polymer derivatives, such as a poly(phenylene vinylene) derivative, a poly(fluorene) derivative, a poly(phenylene) derivative, a poly(thienylene vinylene) derivative, and a poly(acetylene) derivative. It is a matter of course that the host material is not limited thereto.

Examples of the substances having high light emission properties include, for example, a triarylamine derivative, a phenylene derivative, condensed ring aromatic compounds (for example, a fluoranthene derivative, a benzofluoranthene derivative, a pyrene derivative, a chrysene derivative, diarylamine substituted derivatives thereof, and the like), fluorescent materials, such as a stilbene derivative, and phosphorescent materials, such as organic metal complexes (for example, an organic iridium complex, an organic platinum complex, a rare earth metal complex, and the like).

The substance having high light emission properties is also referred to as a guest material. The proportion of the guest material is suitably 0.1% by weight or more and 30 or less % by weight when the entire compound constituting the light emitting layer is 100% by weight. The light emitting layer may emit light of any color. Specifically, primary colors, such as red, green, and blue, neutral colors thereof, or white color may be acceptable.

The hole blocking layer has a HOMO level equal to or higher than the HOMO level of the light emitting layer host and suppresses leakage of holes from the inside of the light emitting layer and injects electrons into the light emitting layer. As the hole blocking layer, hydrocarbon aromatic substances or heterocyclic materials, such as a phenanthroline derivative, a pyridine derivative, and an oxadiazole derivative, can be used.

The electron transport layer contains a material having high electron transport properties capable of efficiently transporting electrons to the hole blocking layer. The electron transporting material is selected considering the balance with the hole mobility of the hole injection layer or the hole transport layer and the like. Materials having electron injection performance or electron transportation performance include condensed ring aromatic compounds (for example, a naphthalene derivative, a phenanthrene derivative, a fluorene derivative, a chrysene derivative, and the like), an oxadiazole derivative, an oxazole derivative, a pyrazine derivative, a triazole derivative, a triazine derivative, a quinoline derivative, a quinoxaline derivative, a phenanthroline derivative, an organic aluminum complex, and the like. It is a matter of course that the materials are not limited thereto.

The electron injection layer is not particularly limited insofar as the layer contains a compound having high electron donation properties and is particularly suitably a metal complex compound. The metal complex compound is an alkaline metal or a metal complex compound containing an alkaline earth metal atom and is particularly suitably an alkali metal complex compound. A ligand of the metal complex compound has a molecular weight of 300 or more and is suitably designed so that the heat stability of the metal complex compound is high and the solubility in water is low.

The electron injection layer may contain a mixed layer of an electron transporting organic compound and a metal complex compound. As the electron transporting material, the same materials as those of the electron transport layer can be used or know electron transporting materials can be used as materials different from the materials of the electron transport layer. For example, materials containing heterocycles and having high electron transporting properties, such as phenanthroline, pyridine, and oxadiazole, can be used as appropriate.

A method for forming the mixed film of the electron transporting material and the metal complex is not particularly limited insofar as a mixed film can be obtained and a codeposition method including vapor-depositing two materials in a vacuum is particularly suitable. Or, the mixed film may be formed by applying a solution in which an electron transporting material and a metal complex compound are dissolved.

The metal complex compound particularly suitably has a lithium complex compound represented by the following general formula [1].

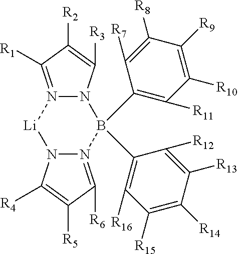

In Formula [1], R₁ to R₁₆ each are independently selected from hydrogen atoms or substituents. The substituent is any one of halogen atoms, alkyl groups, alkoxy groups, and substituted or unsubstituted aryl.

Specific structural formulae of the lithium complex compound according to the present invention are shown below.

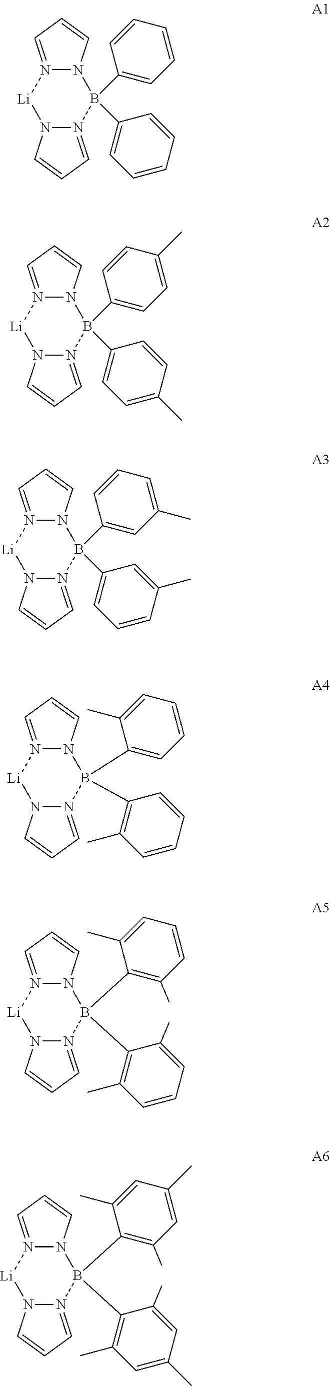

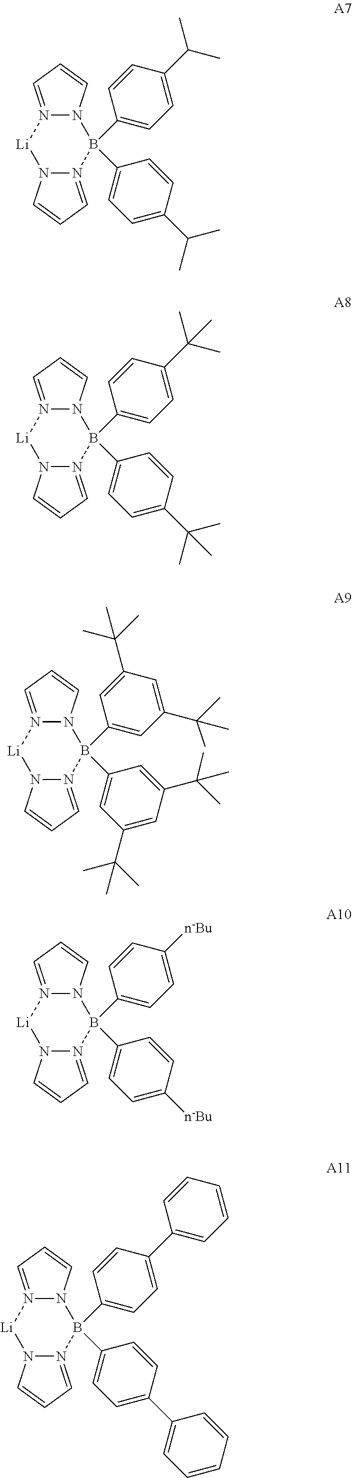

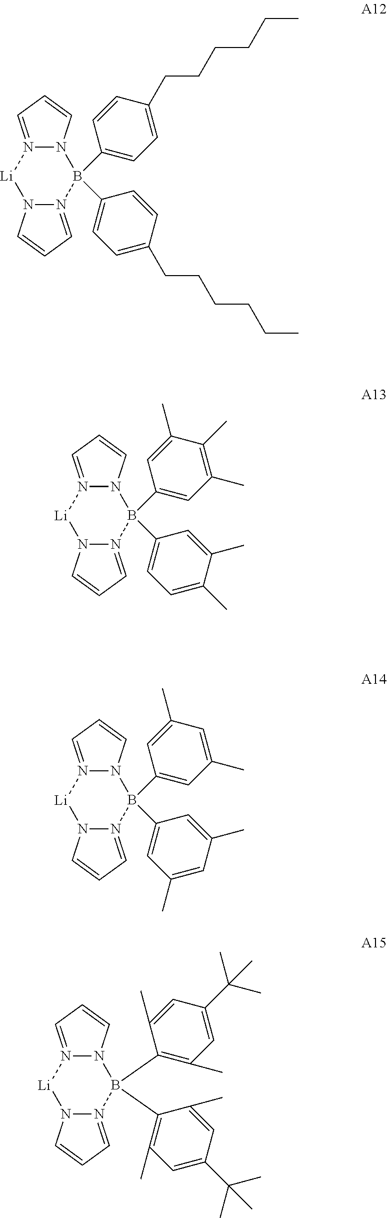

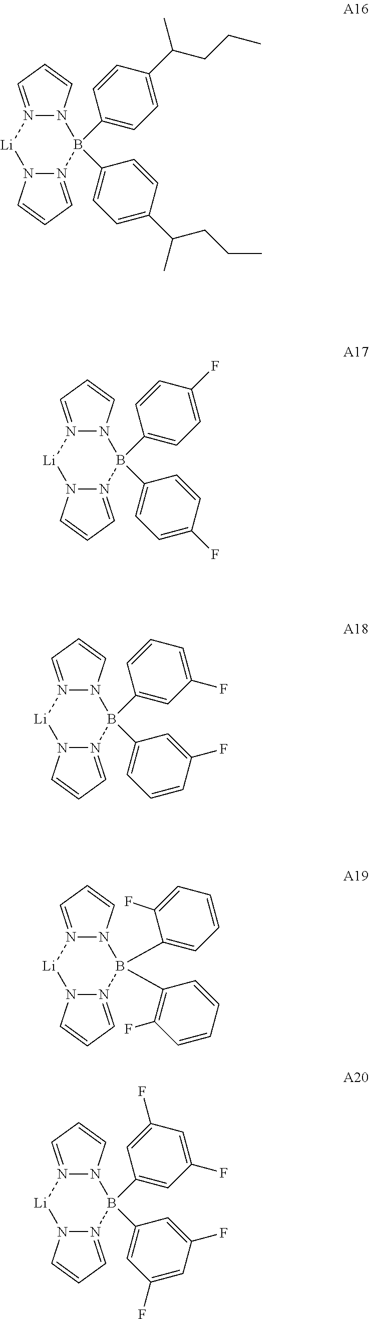

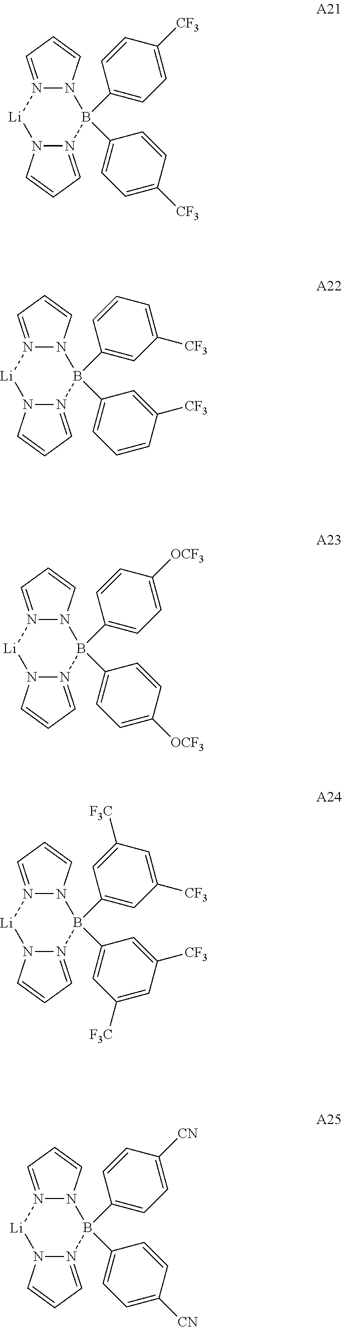

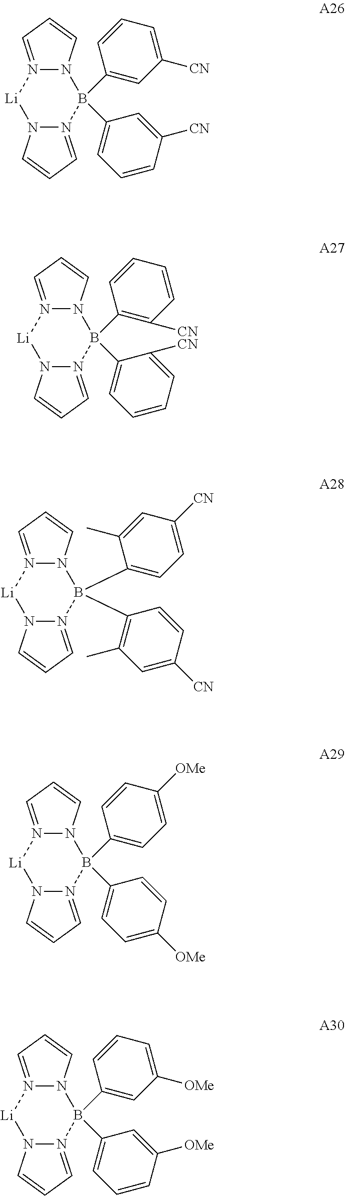

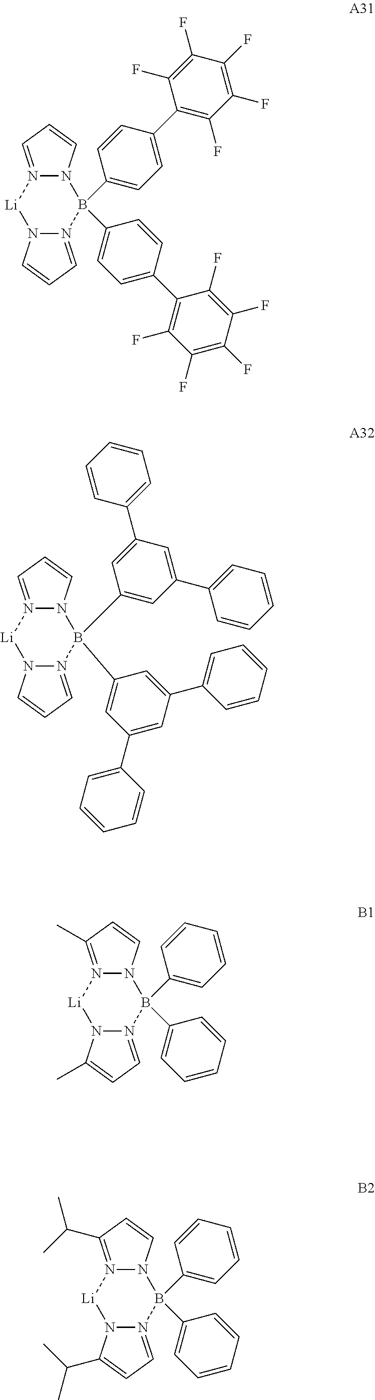

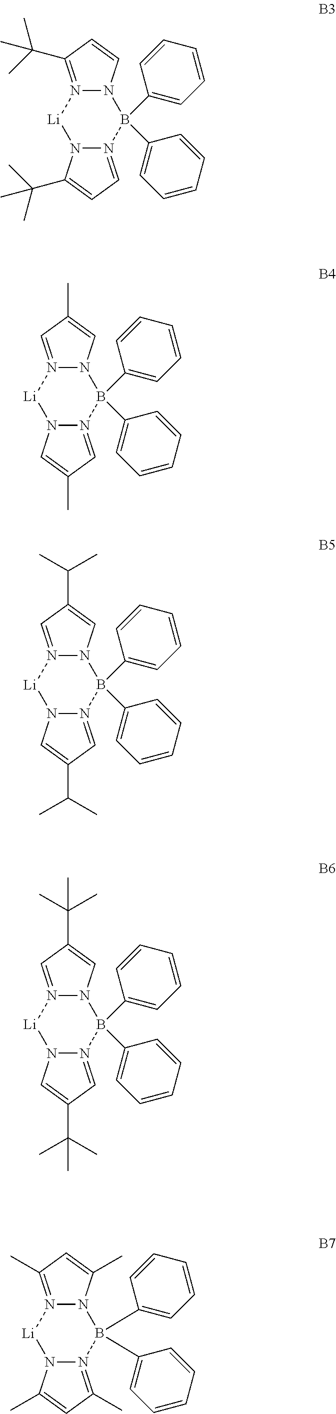

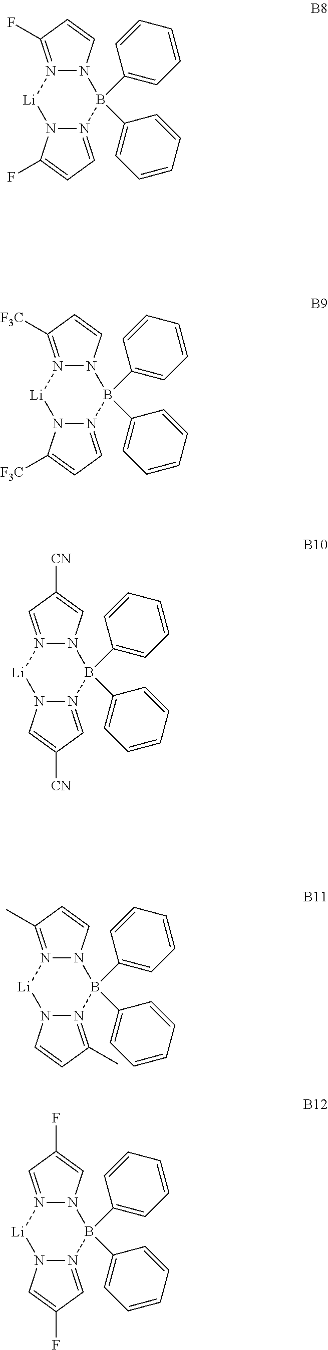

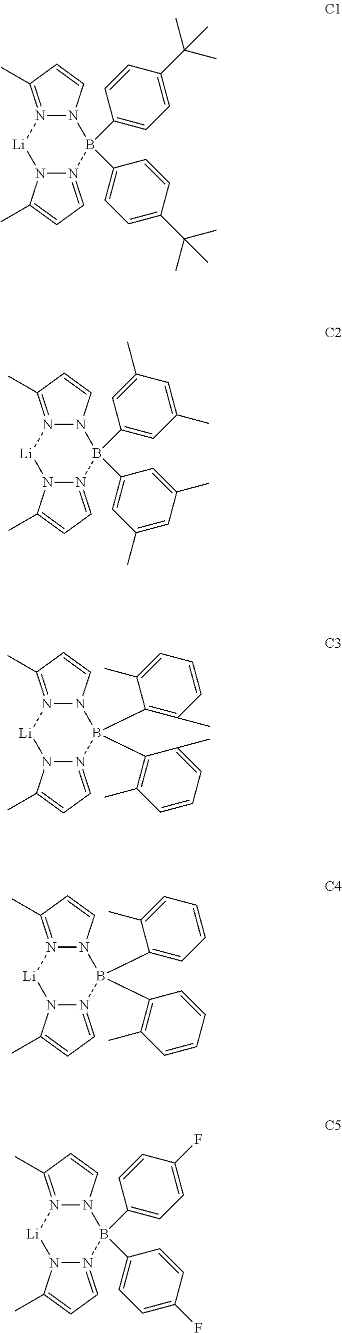

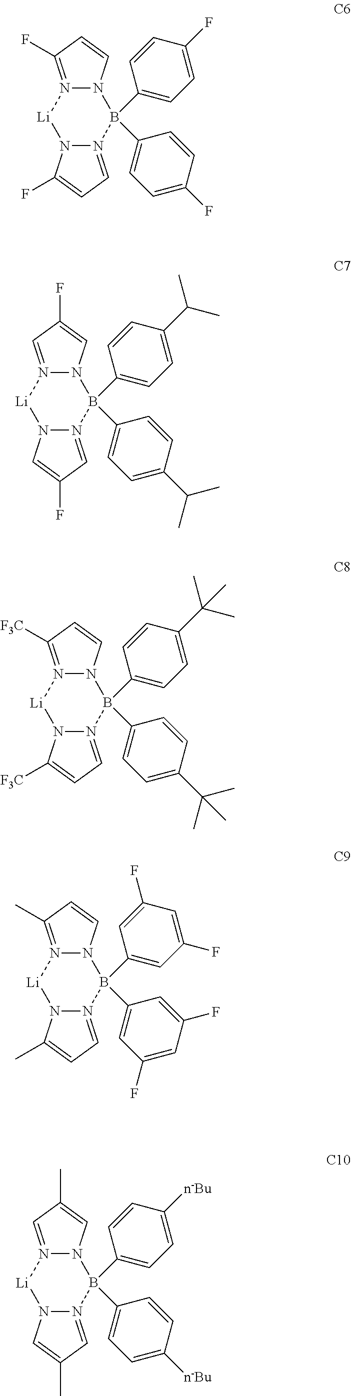

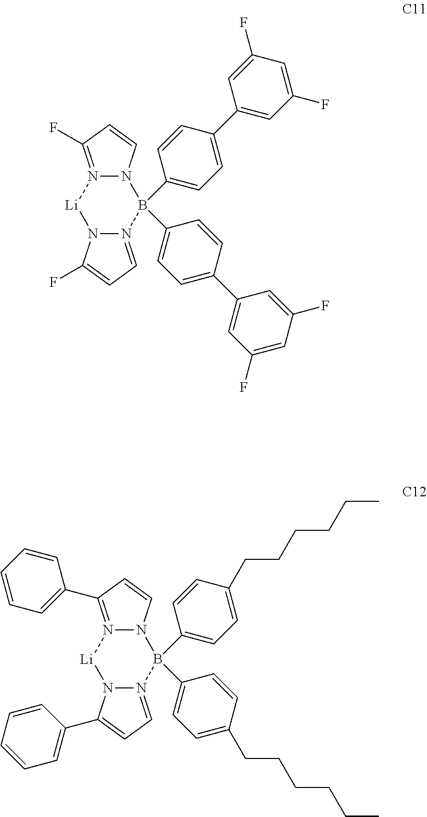

Among the exemplary compounds, compounds shown in the substituent A group have a substituent in a phenyl group which is not bonded to lithium. It is suitable that the compounds have the substituent in a phenyl group which is not bonded to lithium, because the stability of the compounds is high. These lithium compounds are suitable when forming a layer by vapor deposition because the sublimability is high due to having a substituent. In actual, the sublimation temperature can be reduced by providing a fluorine atom and the like. Moreover, by suppressing crystallinity by the introduction of a substituent, the crystallization in fabricating the organic light emitting element can also be suppressed.

In the compounds shown in the B group among the exemplary compounds, a substituent is introduced into a pyrazole group bonded to lithium. When the substituent is provided in the pyrazole group bonded to lithium having low ionization energy, the stability to water further improves by surrounding lithium metal with a substituent. Moreover, by suppressing the crystallinity by the introduction of a substituent, the crystallization in fabricating the organic light emitting element can also be suppressed.

In the compounds shown in the C group among the exemplary compounds, a substituent is introduced into both a pyrazole group and a phenyl group. When the substituent is provided in the pyrazole group bonded to lithium, the stability to water further improves by surrounding lithium metal with a substituent. By providing a substituent in both a pyrazole group and a phenyl group, the crystallinity is suppressed. Therefore, even when the organic compound layer of the organic light emitting element is fabricated by a coating method, the crystallization can be suppressed. Method for synthesizing lithium complex compound according to the present invention

Next, an example of a method for synthesizing an organic compound according to this embodiment is shown. The organic compound according to this embodiment is synthesized according to a reaction scheme shown below, for example.

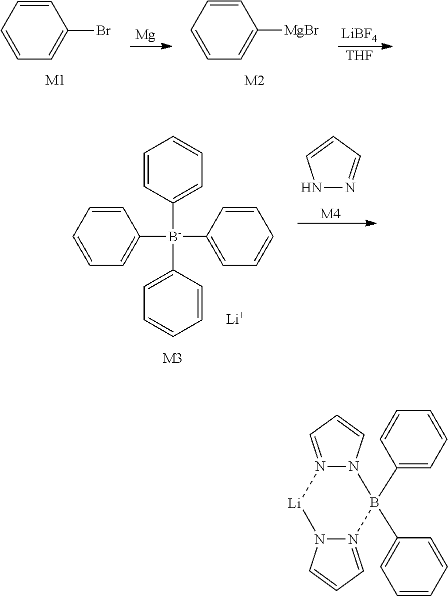

Various lithium complex compounds can be created by introducing substituents, such as an alkyl group, an aryl group, a heteroaryl group, a fluorine atom, a methoxy group, and a cyano group into a hydrogen atom of bromobenzene for use in M1 and introducing substituents, such as an alkyl group, an aryl group, a heteroaryl group, a fluorine atom, a methoxy group, and a cyano group, into a hydrogen atom of pyrazole for use in M4. When a M2 reagent is commercially available, lithium complex compounds can also be synthesized from M2.

As shown by the synthesis scheme, the lithium complex compound according to this embodiment is synthesized.

### Synthesis Example

### Synthesis of Lithium Complex Compound A1

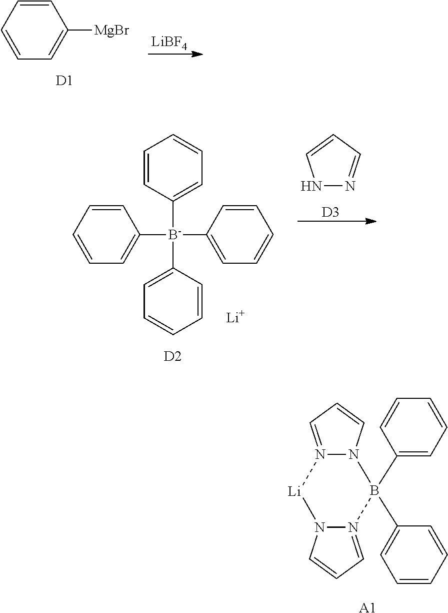

A reagent and a solvent shown below were charged into a 200 mL eggplant flask.

D1: 120 ml (1.0 M THF solution/manufactured by Aldrich) (12.0 mmol)
LiBF₄: 2325 mg (2.5 mmol/manufactured by Wako Pure Chemical Industries, Ltd.)

The reaction solution was stirred for 24 hours. After the end of the reaction, the THF was distilled off under reduced pressure, and then 100 ml of diethylether was added. The solution was gradually added to 150 ml of a 2 M aqueous sodium carbonate solution, and stirred at room temperature for 30 minutes. Thereafter, the organic layer was separated from the aqueous layer, the organic layer was filtered using a Hirsch funnel in which sellite is placed, and then the organic layer was dried using magnesium sulfate. After removing the magnesium sulfate by filtration, the diethylether was distilled off under reduced pressure, and then hexane was added for re-crystallization. The obtained crystal was vacuum-dried to obtain 6.2 g of A1 (Yield of 76%).

The use of the mixed film of the metal complex compound and the electron transporting material as the electron injection layer increases the water resistance of the electron injection layer.

The embodiments of the present invention are described as a method for manufacturing an organic light emitting element and can be utilized for methods for manufacturing a display device and a lighting device containing the organic light emitting element as a constituent member, an exposure light source of an electrophotographic image formation apparatus, and a back light of a liquid crystal display.

### Use of Organic Light Emitting Element of the Present Invention

The organic light emitting element in the present invention can be used as a light source portion of an exposure unit of an image formation apparatus. Specifically, the image formation apparatus has a photoconductor, an exposure portion of exposing the photoconductor, a charging portion of charging the photoconductor, and a development portion of giving a developing agent to the photoconductor, in which the exposure portion has the organic light emitting element of the present invention.

The exposure portion has a plurality of light emitting points and the light emitting points are suitably formed in one line along the major axis direction of the photoconductor. The light emitting point has the organic light emitting element of the present invention.

Hereinafter, an example of an embodiment of an image formation apparatus employing the organic light emitting element according to the present invention is described with reference to the drawing.

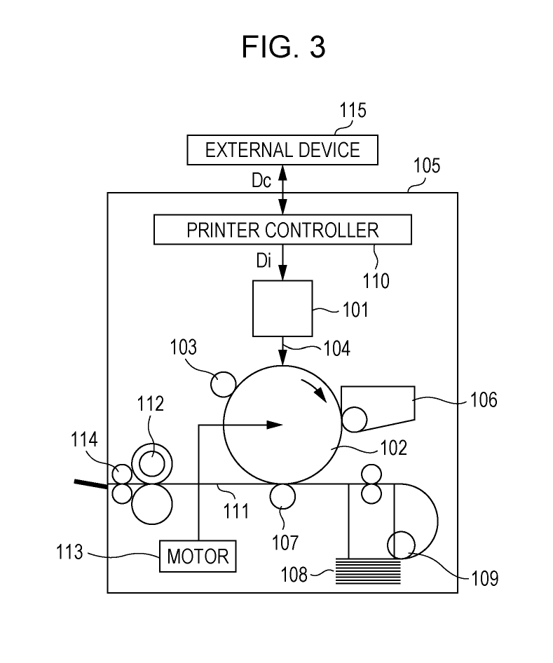

FIG. 3 is a schematic view illustrating an example of the image formation apparatus of the present invention. In FIG. 3, code data Dc are input into an image formation apparatus 105 from an external device 115, such as a personal computer. The code data Dc are converted to image data (dot data) Di by a printer controller 110 in the apparatus. The image data Di are input into an exposure unit 101 having the organic light emitting element. Then, an exposure light 104 modulated according to the image data Di is ejected from the exposure unit 101, and then a photosensitive surface of a photoconductive drum 102 is exposed by the exposure light 104.

The photoconductive drum 102 which is an electrostatic latent image carrier (photoconductor) is clockwisely rotated by a motor 113. Then, the photosensitive surface of the photoconductive drum 102 moves with the rotation in a second direction relative to the exposure light 104. In an upper portion of the photoconductive drum 102, a charging roller 103 which uniformly charges the surface of the photoconductive drum 102 is provided in such a manner abut on the surface. Then, the surface of the photoconductive drum 102 charged by the charging roller 103 is irradiated with the exposure light 104 with the exposure unit 101.

As described above, the exposure light 104 is modulated based on the image data Di. By emitting the exposure light 104, an electrostatic latent image is formed on the surface of the photoconductive drum 102. The electrostatic latent image is developed as a toner image with a development unit 106 disposed in such a manner as to abut the photoconductive drum 102 on a further downstream side in the rotation direction of the photoconductive drum 102 relative to the emission position of the exposure light 104.

A paper feed roller 109 is disposed at an end portion of a paper cassette 108 and feeds paper 111 in the paper cassette 108 into a transportation path. The toner image developed with the development unit 106 is transferred onto the paper 111 with a transfer roller 107 disposed in such a manner as to face the photoconductive drum 102 at a lower portion of the photoconductive drum 102.

As described above, the paper 111 to which an unfixed toner image is transferred is further transported to a fixing unit provided at the back of the photoconductive drum 102. The fixing unit contains fixing rollers 112 having a fixing heater (not illustrated) thereinside and pressurization rollers 114 disposed in such a manner as to be pressure welded to the fixing rollers 112. By heating, under pressurization, the paper 111 transported from the transfer portion in a pressure welding portion of the fixing rollers 112 and the pressurization rollers 114, the unfixed toner image on the paper 111 is fixed.

In the description above, a monochromatic image formation apparatus is described but a full color image formation apparatus can be manufactured by providing an image formation apparatus corresponding to each color of cyan, magenta, yellow, and black side by side.

### EXAMPLES

Hereinafter, the optimal cleaning conditions were selected according to Examples.

### Cleaning Conditions

In the present invention, it is suitable to select cleaning conditions which allow effective removal of foreign matter without causing film separation. When the cleaning conditions are excessively strong, a formed film is damaged or a film is separated in some cases. As a specific example for determining the cleaning conditions, the following experiment was performed. By performing this experiment, appropriate cleaning conditions can be determined. In an actual process, foreign matter to adhere varies in the material, the size, and the like and cannot be completely substituted by polyethylene particles used in this case but the foreign matter removal ratio and the tendency of the film separation can be grasped.

### Conditions of Cleaning Organic Compound Layer

After the end of the formation of the organic compound layer in the formation of the organic light emitting element, 0.2 μm polystyrene particles were dispersed as simulated foreign matter on the organic compound layer. The number of the foreign matter is counted after the dispersion, and then the substrate was cleaned. By counting the number of the foreign matter again after the cleaning, the removal ratio obtained by the cleaning was calculated from the number of the foreign matter before and after the cleaning. Moreover, after the cleaning, it was confirmed whether film separation occurred. In the following table 1, ◯ indicates no film separation and A indicates partial film separation. No film separation is suitable but the film separation with a degree around the degree indicated by Δ in Table 1 is permitted.

The results obtained when the cleaning was performed under the conditions of fixing the water amount of two fluid cleaning 0.35 L/min and changing the N₂ flow rate (L/min) are shown in Table 1.

TABLE 1

| | N₂ flow rate | | | | | | | |
|---|---|---|---|---|---|---|---|---|
| | 10 | 20 | 30 | 40 | 50 | 60 | 70 | 80 |
| Removal ratio (%) | 65.1 | 86.3 | 90.8 | 94.2 | 96.8 | 99.6 | 99.9 | 99.9 |
| Film separation | ∘ | ∘ | ∘ | ∘ | ∘ | ∘ | Δ | Δ |

When the cleaning was performed under the conditions where the N₂ flow was set to 70 L/min or more, the foreign matter removal ratio was able to be made high but film separation occurred in some cases. The N₂ flow rate is suitably 10 L/min or more and 60 L/min or less. From the viewpoint of high foreign matter removal ratio, the N₂ flow rate is more suitably 20 L/min or more and 60 L/min or less. The experiment in which the water amount was changed showed that the water amount is suitably 0.2 L/min or more and 1.0 L/min or less.

### Conditions of Cleaning Upper Electrode

After the end of the formation of the upper electrode, 0.2 μm polystyrene particles were dispersed as simulated foreign matter on the film. The number of the foreign matter is counted after the dispersion, and then the substrate was cleaned. By counting the number of the foreign matter again after the cleaning, the removal ratio obtained by the cleaning was calculated from the number of the foreign matter before and after the cleaning. Moreover, after the cleaning, it was confirmed whether film separation occurred.

The results obtained when the cleaning was performed under the conditions of fixing the water amount of two fluid cleaning at 0.35 L/min and changing the N₂ flow rate (L/min) are shown in Table 2. ◯ and Δ in Table 2 are the same as those in Table 1 above.

TABLE 2

| | N₂ flow rate | | | | | | | |
|---|---|---|---|---|---|---|---|---|
| | 20 | 30 | 40 | 50 | 60 | 70 | 80 | 90 |
| Removal ratio (%) | 58.2 | 76.5 | 83.1 | 89.6 | 92.5 | 95.8 | 98.3 | 99.2 |
| Film separation | ∘ | ∘ | ∘ | ∘ | ∘ | ∘ | ∘ | Δ |

When the cleaning was performed under the conditions where the N₂ flow was set to 90 L/min or more, the foreign matter removal ratio was able to be made high but film separation occurred in some cases. The N₂ flow rate is suitably 20 L/min or more and 80 L/min or less. From the viewpoint of high foreign matter removal ratio, the N₂ flow rate is more suitably 30 L/min or more and 80 L/min or less. The experiment in which the water amount was changed showed that the water amount is suitably 0.05 L/min or more and 2.0 L/min or less.

### Conditions of Cleaning First Protective Layer

After the end of the formation of the upper electrode, 0.2 μm polystyrene particles were dispersed as simulated foreign matter on the film. After the dispersion, 50 nm of SiN was formed into a film as the first protective layer. After the film formation, the number of the foreign matter was counted, and then the substrate was cleaned. By counting the number of the foreign matter again after the cleaning, the removal ratio obtained by the cleaning was calculated from the number of the foreign matter before and after the cleaning. Moreover, after the cleaning, it was confirmed whether film separation occurred.

The results obtained when the cleaning was performed under the conditions of fixing the water amount of two fluid cleaning at 0.35 L/min and changing the N₂ flow rate (L/min) are shown in Table 3. ◯ and Δ in Table 2 are the same as those in Table 1 above.

TABLE 3

| | N₂ flow rate | | | | | | | |
|---|---|---|---|---|---|---|---|---|
| | 40 | 60 | 80 | 100 | 120 | 140 | 160 | 180 |
| Removal ratio (%) | 45.2 | 82.1 | 93.1 | 98.3 | 98.9 | 99.2 | 99.3 | 99.3 |
| Film separation | ∘ | ∘ | ∘ | ∘ | ∘ | ∘ | ∘ | Δ |

When the cleaning was performed under the conditions where the N₂ flow was set to 180 L/min or more, the foreign matter removal ratio was able to be made high but film separation occurred in some cases. The N₂ flow rate is suitably 40 L/min or more and 160 L/min or less. From the viewpoint of high foreign matter removal ratio, the N₂ flow rate is more suitably 60 L/min or more and 160 L/min or less. The experiment in which the water amount was changed showed that the water amount is suitably 0.05 L/min or more and 2.0 L/min or less.

### Heating Process for Removing Liquid Containing Water

With respect to the desorption temperature of moisture from the organic compound layer, thermal desorption spectroscopy was performed. When the substrate on which the organic compound layer was formed was heated in a vacuum after the two fluid cleaning, the desorption of moisture was observed at about 80° C. and about 115° C. Therefore, in the process of performing heating in order to remove the liquid containing water, it is suitable to increase the temperature to 115° C. or higher.

### Example 1

In this example, an organic light emitting element was fabricated by performing a process of cleaning an organic compound layer with liquid containing water.

The name of the processes correspond to processes A to H of the embodiments described above.

### (A) Process of Forming Lower Electrode

ITO was formed into a film on a glass substrate, and then subjected to patterning processing to thereby form a lower electrode. In this process, the film thickness of the lower electrode was set to 100 nm. Thereafter, UV ozone treatment was performed as surface treatment of the lower electrode.

### (B) Process of Forming Organic Compound Layer

Next, organic compounds shown below were vapor deposited by a vacuum deposition method at a desired position on the lower electrode using a mask to form an organic compound layer.

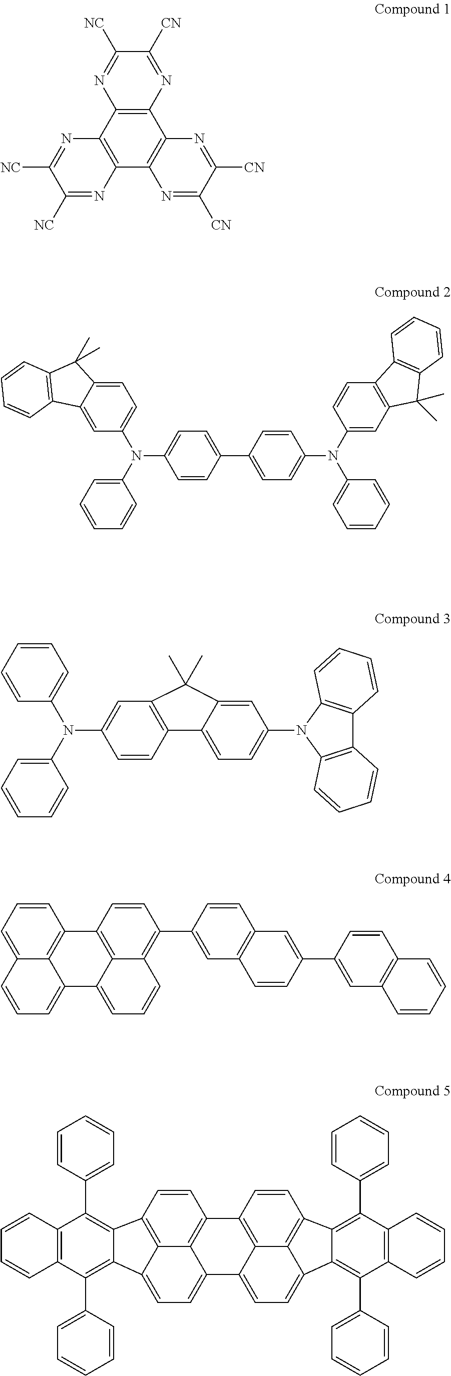

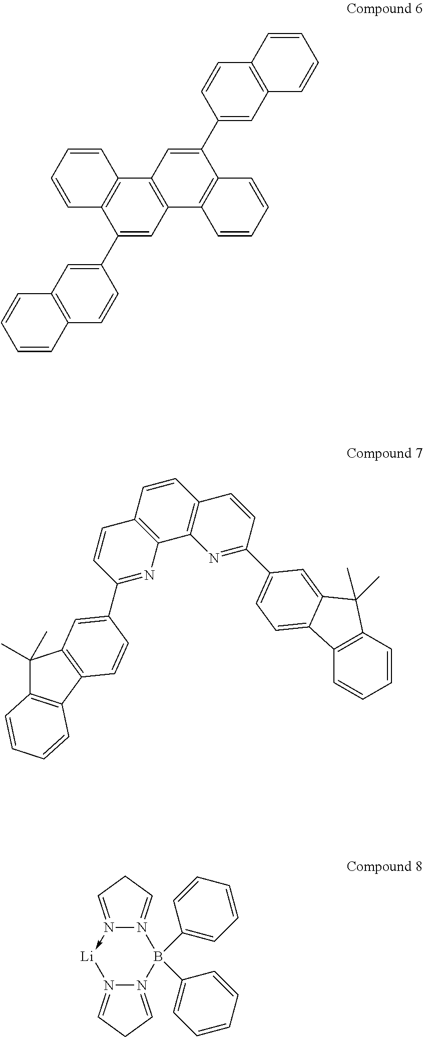

As a hole injection layer, 3 nm of the compound 1 was formed. As a hole transport layer, 50 nm of the compound 2 was formed. As an electron blocking layer, 10 nm of the compound 3 was formed. Then, as a light emitting layer, codeposition was performed in such a manner that 1 wt % of the compound 5 as a light emitting material was contained in the compound 4 as a host material to form a film with a thickness of 20 nm. Furthermore, 10 nm of the compound 6 was formed into a film as a hole blocking layer, 40 nm of the compound 7 was formed into a film as an electron transport layer, and then the compound 7 and the compound 8 were codeposited in such a manner that the weight concentration ratio was 1:1 to form a film in such a manner as to have a film thickness of 15 nm in order.

### (C) Process of Cleaning Organic Compound Layer Using Liquid Containing Water

The substrate on which the organic compound layer was formed was exposed to the air, and then cleaned under the following conditions. This process was performed under a yellow light from the process of forming the organic compound layer, and then exposing the organic compound layer to the air to the end of the cleaning.

For the cleaning, two fluid cleaning is used, and the conditions of the two fluid cleaning are as follows. Water flow rate 0.34 L/min, Nitrogen flow rate 40 L/min Substrate rotation speed 150 rpm

Cleaning time 40 seconds

Thereafter, the number of rotations of the substrate was set to 1500 rpm, and spin drying was performed for 150 seconds. Furthermore, the cleaned substrate was transported to a vacuum chamber, and then the organic compound layer was heated with a halogen lamp heater for 20 minutes under reduced pressure of 1×10⁻⁴ Pa in such a manner that the substrate temperature was 120° C.

### (D) Process of Forming Upper Electrode on Organic Compound Layer

100 nm of aluminum (Al) was formed by vacuum deposition as an upper electrode at a desired position using a mask.

### (F) Process of Forming First Protective Layer Contacting Upper Electrode

### (H) Process of Forming Second Protective Layer Contacting First Protective Layer

Next, a protective layer containing SiN was formed. In this example, since a process of cleaning a first protective layer was not performed, a first protective layer and a second protective layer were successively formed. On the substrate which was subjected to the process (D), 2 μm of SiN was formed into a film by CVD film formation using SiH₄ and N₂ as reactive gas. Thereafter, the silicon nitride film was patterned by photolithography to expose a pad electrode for external connection.

### Comparative Example 1

As Comparative Example 1, an organic light emitting element was fabricated by processes not having the process (C) in Example 1, i.e., a process which does not include performing the process of cleaning an organic compound layer.

Evaluation of Non-Light Emitting Part of Organic Light Emitting Element

The organic light emitting elements of Example 1 and Comparative Example 1 were placed in an environment of a temperature of 85° C. and a humidity of 85% for 18 hours, and then the generation density of the non-light emitting parts was evaluated. As a result, while the generation density of the non-light emitting parts is 1.5 pieces/cm² in Comparative Example 1, the generation density is 0.18 pieces/cm² in Example 1. Thus, it was able to be confirmed that the generation density of the non-light emitting parts can be suppressed in the organic light emitting element fabricated in Example 1.

This is considered to be because foreign matter is removed from the organic compound layer by the cleaning process, and, as a result, the generation of an entry path of water and oxygen from the outside in the protective layer can be suppressed.

### Example 2

In Example 2, an organic light emitting element was fabricated according to processes not having the process (C) in Example 1 and having the process (E) of cleaning an upper electrode with liquid containing water after the process (D) of forming upper electrode on organic compound layer in Example 1. Hereinafter, the processes (A), (B), (D), (F) and (H) in this Example are the same as those of Example 1.

(E) Process of Cleaning Upper Electrode with Liquid Containing Water

The substrate on which the organic compound layer and the upper electrode were formed was exposed to the air, and then cleaned under the following conditions. This process was performed under a yellow light from the process of forming the upper electrode, and then exposing the organic upper electrode to the air to the end of the cleaning.

For the cleaning, two fluid cleaning is used, and the conditions of the two fluid cleaning are as follows. Water flow rate 0.34 L/min, Nitrogen flow rate 60 L/min Substrate rotation speed 500 rpm

Cleaning time 40 seconds

Thereafter, the number of rotations of the substrate was set to 1500 rpm, and spin drying was performed for 150 seconds. Furthermore, the cleaned substrate was transported to a vacuum chamber, and then the organic compound layer and the upper electrode were heated with a halogen lamp heater for 20 minutes under reduced pressure of 1×10⁻⁴ Pa in such a manner that the substrate temperature was 120° C.

### Evaluation of Non-Light Emitting Part of Organic Light Emitting Element

The organic light emitting elements of Example 2 and Comparative Example 1 were placed in an environment of a temperature of 85° C. and a humidity of 85% for 18 hours to be evaluated for the generation density of the non-light emitting parts. As a result, while the generation density of the non-light emitting parts is 1.5 pieces/cm² in Comparative Example 1, the generation density is 0 piece/cm² in Example 2. Thus, it was able to be confirmed that the generation density of the non-light emitting parts can be suppressed in the organic light emitting element fabricated in Example 2.

By providing the cleaning process as in Example 2, the generation and the growth and expansion of a dark spot (DS) can be suppressed. This is considered to be because foreign matter is removed from the organic compound layer and the upper electrode by the cleaning process, and, as a result, the generation of an entry path of water and oxygen from the outside in the protective layer can be suppressed.

### Confirmation of Protective Layer of Foreign Matter Removal Portion

In order to confirm the presence or absence of defects of the protective layer of the foreign matter removal portion, the organic light emitting element of Example 2 was subjected to the following evaluation. First, the position assumed to be the foreign matter removal portion of the organic light emitting element was specified by transmitted light observation under an optical microscope (Olympus MX80).

Next, FIB processing was performed using an FIB/SEM apparatus (NOVA600 NANOLAB manufactured by FEI) in such a manner as to expose the vertical cross-sectional portion of the specified position. Then, SEM observation of the cross-sectional portion was performed using the apparatus. As a result, it was able to be observed that the organic compound layer and the upper electrode were partially removed at the position assumed to be the foreign matter removal portion, and the portion was specified to be a characteristic foreign matter removal trace formed by the cleaning. It was found that the protective layer above the foreign matter removal trace was free from defects and normally functions as the protective layer. The foreign matter removal trace does not emit light but the non-light emission region is about 800 nm, and therefore it was confirmed that the foreign matter removal trace does not pose any problems in actual use.

### Example 3

In Example 3, an organic light emitting element was fabricated according to processes not having the process (C) in Example 1 and having the process (G) of cleaning a first protective layer with liquid containing water and the process (H) of forming a second protective layer on the first protective layer after the process (F). In this example, the processes (A) and (B) are the same as those of Example 1.

### (F) Process of Forming First Protective Layer Contacting Upper Electrode

A protective layer containing SiN was formed. On the substrate which was subjected to the process (D), 500 nm of SiN was formed into a film by CVD film formation using SiH₄ and N₂ as reactive gas.

(G) Process of Cleaning First Protective Layer with Liquid Containing Water

The substrate on which the organic compound layer, the upper electrode, and the first protective layer were formed was exposed to the air, and then cleaned under the following conditions. This process was performed under a yellow light from the process of forming the first protective layer, and then exposing the first protective layer to the air to the end of the cleaning.

For the cleaning, two fluid cleaning is used, and the conditions of the two fluid cleaning are as follows. Pure water flow rate 1.5 L/min, Nitrogen flow rate 160 L/min Substrate rotation speed 500 rpm

Cleaning time 30 seconds

Thereafter, the number of rotations of the substrate was set to 1500 rpm, and spin drying was performed for 150 seconds. Furthermore, the cleaned substrate was transported to a vacuum chamber, and then the organic compound layer, the upper electrode, and the first protective layer were heated with a halogen lamp heater for 20 minutes under reduced pressure of 1×10⁻⁴ Pa in such a manner that the substrate temperature was 120° C.

### (H) Process of Forming Second Protective Layer on First Protective Layer

A protective layer containing SiN was formed. On the substrate which was subjected to the process (G), 1500 nm of SiN was formed into a film by CVD film formation using SiH₄ and N₂ as reactive gas.

### Example 4

In this Example, an element was fabricated in the same manner as in Example 3, except changing the layer thickness of the first protective layer, the cleaning conditions of the two fluid cleaning, and the layer thickness of the second protective layer.

The film thickness of the first protective layer of this example is 200 nm. The cleaning conditions of the two fluid cleaning are N₂: 100 L/min and H₂O: 0.35 L/min. The thickness of the second protective layer is 1.8 μm.

### Example 5

In this Example, an element was fabricated in the same manner as in Example 3, except changing the layer thickness of the first protective layer, the cleaning conditions of the two fluid cleaning, and the layer thickness of the second protective layer.

The film thickness of the first protective layer of this example is 100 nm. The cleaning conditions of the two fluid cleaning are N₂: 80 L/min and H₂O: 0.5 L/min. The thickness of the second protective layer is 1.9 μm.

### Example 6

In this Example, an element was fabricated in the same manner as in Example 3, except changing the layer thickness of the first protective layer, the cleaning conditions of the two fluid cleaning, and the layer thickness of the second protective layer.

The film thickness of the first protective layer of this example is 50 nm. The cleaning conditions of the two fluid cleaning are N₂: 70 L/min and H₂O: 0.35 L/min. The thickness of the second protective layer is 1.95 μm.

### Example 7

In this Example, an element was fabricated in the same manner as in Example 3, except changing the layer thickness of the first protective layer, the cleaning conditions of the two fluid cleaning, and the layer thickness of the second protective layer.

The film thickness of the first protective layer of this example is 20 nm. The cleaning conditions of the two fluid cleaning are N₂: 50 L/min and H₂O: 0.3 L/min. The thickness of the second protective layer is 1.98 μm.

### Example 8

An organic light emitting element of this example has a top emission configuration. Processes other than the processes (A) and (D) in Example 4 are the same as those in Example 4. Specifically, a lower electrode was changed to Ag (100 nm)/ITO (40 nm) and an upper electrode was changed to Ag (10 nm).

### Evaluation of Non-Light Emitting Part of Organic Light Emitting Element

The organic light emitting elements of Example 3 to Example 8 and Comparative Example 1 were placed in an environment of a temperature of 85° C. and a humidity of 85% for 18 hours to be evaluated for the generation density of the non-light emitting parts. The results are shown in Table 4.

TABLE 4

| | Ex. 3 | Ex. 4 | Ex. 5 | Ex. 6 | Ex. 7 | Ex. 8 | Comp. Ex. 1 |
|---|---|---|---|---|---|---|---|
| Film thickness of first | 500 | 200 | 100 | 50 | 20 | 200 | 200 |
| protective layer (nm) | | | | | | | |
| Top emission | — | — | — | — | — | ∘ | — |
| DS generation density | 0.70 | 0.25 | 0.13 | 0.19 | 0.32 | 0.19 | 1.50 |
| (Pieces/cm²) | | | | | | | |

In the element fabricated in Example 3, the generation density of the non-light emitting parts after placed in the environment of a temperature of 85° C. and a humidity of 85% for 18 h was suppressed as compared with the generation density of Comparative Example 1. This is considered to be because, by providing the cleaning process, foreign matter is removed from the substrate, and, as a result, the generation of defects in the protective layer is suppressed, and therefore the entry of water from the outside can be suppressed.

In the elements fabricated in Example 4 to Example 7, since the generation density of the non-light emitting parts is further suppressed, the first protective layer suitably has a film thickness of 200 nm or less.

Also in Example 8, the generation density of the non-light emitting parts after placed in the environment of a temperature of 85° C. and a humidity of 85% for 18 h was suppressed. In the case of the top emission configuration, an upper electrode of thin film metal (for example, Al, Ag, AgMg, and the like) is used as in Example 8, and thus the tolerance for cleaning without the protective layer may not be sufficient. In that case, the cleaning tolerance can be sharply increased by forming the first protective layer.

### Heating Process

### Example 9

In this example, an organic light emitting element was fabricated according to the same processes as those of Example 1, except that the process (C) in Example 1 was different from that in this example.

In this example, in the process (C), a heating process was provided after cleaning the organic compound layer with liquid containing water. In the heating process, the organic compound layer was heated with a halogen lamp heater for 20 minutes in such a manner that substrate temperature was 112.5° C.

### Example 10

In this example, an organic light emitting element was fabricated in the same manner as in Example 9, except that the substrate temperature of the heating process in Example 9 was different from that in this example.

In this example, in the heating process, the organic compound layer was heated with a halogen lamp heater for 20 minutes in such a manner that substrate temperature was 142.5° C.

### Comparison of Example 9 and Example 10

A durability test was carried out by applying a fixed current of 80 mA/cm² to the organic light emitting elements of Example 9 and Example 10. When the luminance reduction rate after 200 hours passed was compared, the luminance reduction rate was 9.5% in Example 9 in which the heating was performed at 112.5° C. but the luminance reduction rate was 4.3% in Example 10 in which the heating was performed at 142.5° C. This is considered that, in the organic light emitting element heated to 115° C. or higher, moisture is further removed, so that the durability properties improve. Therefore, in order to obtain better durability properties, it is suitable to set the substrate temperature in the heating to 115° C. or higher.

### Comparison of Electron Injection Material

### Comparative Example 2

An organic light emitting element was fabricated according to the same processes as those of Example 1, except that the process (B) was different from that in Example 1. In this comparative example, an organic light emitting element was obtained by performing codeposition so that the proportion of cesium carbonate was 3 vol % based on the compound 7 to form a film with a layer thickness of 15 nm as an electron injection layer.

### Comparison of Example 1 and Comparative Example 2

A fixed current of 100 mA/cm² was applied to the organic light emitting elements of Example 1 and Comparative Example 2, and then a driving voltage in the application was evaluated. While the driving voltage was 5.7 V in Example 1, the driving voltage was 6.8 V in Comparative Example 2. This shows that the metal complex compound in the present invention is hardly affected by the cleaning and has excellent water resistance.

The present invention has the process of cleaning at least one of the organic compound layer, the upper electrode, or the first protective layer with liquid containing water. Thus, the present invention can provide a method for manufacturing an organic light emitting element in which foreign matter present in the element is removed and an entry path of moisture and oxygen is difficult to be formed in a protective layer.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2014-067098, filed Mar. 27, 2014, 2014-184400, filed Sep. 10, 2014, 2014-184401, filed Sep. 10, 2014, and 2015-011628, filed Jan. 23, 2015 which are hereby incorporated by reference wherein in their entirety.

What is claimed is:

1. A method for manufacturing an organic light emitting element comprising:
forming a lower electrode;
forming an organic compound layer on the lower electrode;
forming an upper electrode on the organic compound layer;
forming a first protective layer on the upper electrode; and
forming a second protective layer on the first protective layer wherein
the method includes, after the formation of the organic compound layer, cleaning at least one of the organic compound layer, the upper electrode, and the first protective layer with liquid containing water.

2. The method for manufacturing an organic light emitting element according to claim 1, wherein the cleaning with liquid containing water is cleaning of the organic compound layer with liquid containing water.

3. The method for manufacturing an organic light emitting element according to claim 2, wherein
the formation of the organic compound layer is formation of a light emitting layer and an organic compound layer different from the light emitting layer, and
the cleaning of the organic compound layer with liquid containing water is cleaning of the organic compound layer different from the light emitting layer with liquid containing water.

4. The method for manufacturing an organic light emitting element according to claim 3, wherein the organic compound layer different from the light emitting layer is an organic compound layer contacting the upper electrode.

5. The method for manufacturing an organic light emitting element according to claim 1, wherein the cleaning with liquid containing water is cleaning of the upper electrode with liquid containing water.

6. The method for manufacturing an organic light emitting element according to claim 1, wherein the cleaning with liquid containing water is cleaning of the first protective layer with liquid containing water.

7. The method for manufacturing an organic light emitting element according to claim 6, wherein the first protective layer has a layer thickness smaller than a layer thickness of the second protective layer.

8. The method for manufacturing an organic light emitting element according to claim 6, wherein the layer thickness of the first protective layer is 20 nm or more and 200 nm or less.

9. The method for manufacturing an organic light emitting element according to claim 6, wherein the first protective layer is silicon nitride.

10. The method for manufacturing an organic light emitting element according to claim 1, wherein the cleaning with liquid containing water is two fluid cleaning.

11. The method for manufacturing an organic light emitting element according to claim 9, wherein the two fluid cleaning is two fluid cleaning with nitrogen and water.

12. The method for manufacturing an organic light emitting element according to claim 1, comprising, after the cleaning with liquid containing water, heating the cleaned layer.

13. The method for manufacturing an organic light emitting element according to claim 12, wherein the heating is heating under reduced pressure.

14. The method for manufacturing an organic light emitting element according to claim 12, wherein the heating is performed at a temperature of 115° C. or higher.

15. The method for manufacturing an organic light emitting element according to claim 1, wherein
the organic compound layer contains an organic compound and an organic metal complex, and
the organic metal complex contains an organic metal complex represented by General Formula [1] shown below, 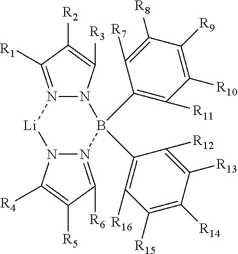
wherein, in Formula [1], R₁ to R₁₆ each are independently selected from a hydrogen atom or a substituent and the substituent is any one of a halogen atom, an alkyl group, an alkoxy group, or substituted or unsubstituted aryl.

16. The method for manufacturing an organic light emitting element according to claim 4, wherein the organic compound layer contacting the upper electrode and different from the light emitting layer contains an organic compound and an organic metal complex, wherein
the organic metal complex is represented by General formula [1] shown below, 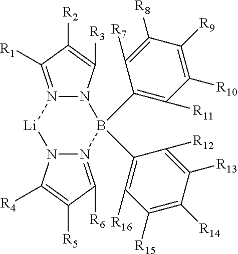
wherein, in Formula [1], R₁ to R₁₆ each are independently selected from a hydrogen atom or a substituent and the substituent is any one of a halogen atom, an alkyl group, an alkoxy group, or substituted or unsubstituted aryl.

17. The method for manufacturing an organic light emitting element according to claim 1, wherein the cleaning with liquid containing water includes cleaning the organic compound layer with liquid containing water, cleaning the upper electrode with liquid containing water, and cleaning the first protective layer with liquid containing water.

18. An image formation apparatus comprising:
a photoconductor;
an exposure portion of exposing the photoconductor;
a charging portion of charging the photoconductor; and
a development portion of giving a developing agent to the photoconductor, wherein
the exposure portion is the organic light emitting element manufactured by the method for manufacturing an organic light emitting element according to claim 1.

19. An exposure apparatus having a photoconductor,
the exposure apparatus comprising a plurality of light emitting points, wherein
the light emitting point is an organic light emitting element manufactured by the method for manufacturing an organic light emitting element according to claim 1, and
the plurality of light emitting points are formed in one line along the photoconductor.
